(19) United States
(12) Patent Application Publication
(10) Pub. No.: US 2012/0276718 A1
(43) Pub. Date: Nov. 1, 2012

(54) METHOD OF FABRICATING GRAPHENE-BASED FIELD EFFECT TRANSISTOR

(75) Inventors: Xinhong Cheng, Shanghai (CN); Youwei Zhang, Shanghai (CN); Dawei Xu, Shanghai (CN); Zhongjian Wang, Shanghai (CN); Chao Xia, Shanghai (CN); Dawei He, Shanghai (CN); Yuehui Yu, Shanghai (CN)

(73) Assignee: SHANGHAI INSTITUTE OF MICROSYSTEM AND INFORMATION TECHNOLOGY, CHINESE ACADEMY, SHANGHAI (CN)

(21) Appl. No.: 13/145,033

(22) PCT Filed: Jun. 8, 2011
(86) PCT No.: PCT/CN11/75426

§ 371 Date: Jul. 18, 2011

(30) Foreign Application Priority Data
Apr. 27, 2011 (CN) 201110106410.0

(51) Int. Cl. H01L 21/283

(52) U.S. Cl. 438/478; 257/E21.159

(57) ABSTRACT

The present invention provides a method of fabricating a graphene-based field effect transistor, which includes steps of: providing a semiconductor substrate on which a non-functionized graphene layer is formed; forming a metal oxide film as a nucleation layer through a reaction between a metal source and water which acts as oxidizer and is physically absorbed to a surface of the graphene layer; and generating a HfO₂ gate dielectric layer through a reaction between a hafnium source and water acting as oxidizer by using the nucealtion layer. In comparison with the prior art, the method of the present invention is mainly characterized in that the metal oxide film acting as the nucleation layer is formed through a reaction between the metal source and water which acts as oxidizer and is physically absorbed to the surface of graphene. This enables a HfO₂ gate dielectric film to be prepared later on with an atomic layer deposition process to have good uniformity, a high coverage rate, and a high quality and prevents the defects which may degrade the performance of the graphene-based field effect transistor from entering the crystal lattice of graphene.

### FIELD OF THE INVENTION

The present invention relates to fabrication of semiconductor devices, and particularly to a method of fabricating graphene-based field effect transistors.

### BACKGROUND OF THE INVENTION

According to Moore's law, the number of transistors that may be placed on a chip is doubled between eighteen months and two years, which means that the minimum line width of transistor on the chip may be reduced to half It is generally believed that the minimum line width of transistor for silicon materials may be minimized to 10 nm, and it is coming to an end to extend Moore's law using a silicon-based semiconductor whose dimension is becoming increasingly smaller. With reduction in dimension of microelectronic devices, the minimum line width for the silicon material is reaching a limit.

To extend the Moore's law, beyond silicon technology has been proposed in the international semiconductor industrial field. In these circumstances, graphene has emerged as the most promising material. Graphene, which is a new carbon crystal with a two-dimensional honeycomb lattice, has captured extensive concerns throughout the world.

Graphene is a monolayer carbon film originally obtained by exfoliation from graphite. In a two-dimensional plane, each carbon atom is connected by sp² hybridization. That is to say that each carbon atom forms three σ bonds with its three nearest-neighbor carbon atoms thereof, the rest one p electron in vertical to a graphene plane forms a π bond with adjacent atoms thereof, and carbon atoms form an orthohexagonal planar honeycomb structure, which thus means that only two kinds of atoms different in spatial position exist on the same atomic surface. Experiments show that graphene has unique electrical properties as well as excellent mechanical properties and thermal stabilities. Graphene is a zero-gap material. Moreover, electrons of graphene each have an effective mass of zero, move at a constant speed of 10⁶ m/s, and behave in a similar way to photons. Therefore, with a theoretical electron mobility up to 200,000 cm²/V·s, graphene has an experimentally-measured electron mobility beyond 15,000 cm²/V·s which is ten times that of commercial silicon wafers, and also has novel physical properties such as room-temperature integer quantum Hall effects. The excellent electrical properties of graphene make it possible to develop graphene-based transistors and integrated circuits, and possibly enable graphene to be a complete substitute for silicon wafers to be a new-generation major semiconductor material.

As the new semiconductor material, graphene has been used in metal-oxide-semiconductor field effect transistors. To fabricate a high-performance graphene-based ii field effect transistor, it is necessary to prepare a high-quality high-k gate dielectric on a surface of graphene. It is possible to deposit a gate dielectric film directly on the surface of graphene by a physical vapor deposition process, but the thus-deposited gate dielectric film has poor uniformity and a low coverage rate. Furthermore, kinetic ions may unavoidably destroy the structure of graphene during the deposition process, introducing a large quantity of defects. This thus leads to a large decline in the electrical properties of graphene. In addition, using a chemical vapor deposition (abbreviated as CVD) process may prevent the kinetic ions from causing any damage and enables the film to be deposited to have good uniformity and a high coverage rate. However, the film deposited by the CVD process has a high content of defects. As far as the high-k gate dielectric film is concerned, defects may largely reduce the dielectric constant and greatly affect device performance. This poses limitation on the CVD process in preparing high-k gate dielectrics. Moreover, an atomic layer deposition (abbreviated as ALD) process, which depends on an alternating repeated self-limiting reaction to grow films and is considered as the most probable method of obtaining a high-quality high-k dielectric layer, enables an accurate control on thickness and chemical compositions of the films to be deposited, so the deposited films has few defects, a high quality, good uniformity and good conformality. However, the surface of graphene is hydrophobic and lacks dangling bonds required for growing films, thus making it difficult to use a H₂O-based ALD process to obtain a uniform ultra-thin high-k dielectric layer on a non-functionalized surface of graphene. On the other hand, using an O₃-based ALD process enables preparation of a high-k dielectric layer on graphene, but experiments show that O₃ may destroy C—C bonds of graphene and introduce a large quantity of C—O bonds, thus destroying a crystal structure of graphene and degrading performance of the graphene-based field effect transistors. Therefore, it has become a big challenge to prepare a high-quality oxide gate dielectric on the graphene surface without destroying the graphene structure and degrading the electrical properties of graphene.

### SUMMARY OF THE INVENTION

An objective of the present invention is to provide a method of fabricating a graphene-based field effect transistor to solve problems existent in the prior art such as that an oxide gate dielectric layer prepared on a surface of graphene has poor uniformity, a low coverage rate, and a large quantity of defects and that a crystal structure of graphene is destroyed.

The method of fabricating a graphene-based field effect transistor comprises the following steps of: providing a semiconductor substrate on which a non-functionized graphene layer is formed; forming a metal oxide film as a nucleation layer through a reaction between a metal source and water which acts as oxidizer and is physically absorbed to a surface of the graphene layer; and generating a HfO₂ gate dielectric layer through a reaction between a hafnium source and water acting as oxidizer.

It is preferred that the graphene layer is formed on the semiconductor substrate by transferring a non-functionzied graphene sample to the semiconductor substrate.

Further, it is preferred that the metal oxide film is Al₂O₃ film, and the Al₂O₃ film is formed by repeating a reaction cycle composed of steps of: transferring the semiconductor substrate having the graphene layer to a reactor; heating the reactor to a first reaction temperature; and generating the Al₂O₃ film with an ALD process through a reaction between an aluminum source and water which acts as oxidizer and is physically absorbed to the surface of the graphene layer.

Further, it is preferred that the first reaction temperature is in a range of from 100° C. to 140° C.

Further, it is preferred that the aluminum source is trimethylaluminum.

Further, it is preferred that the Al₂O₃ film is obtained by repeating the reaction cycle 10 times to 35 times.

Further, it is preferred that a thickness of the Al₂O₃ film is in a range of from 1.5 nm to 5 nm.

Further, it is preferred that the HfO₂ gate dielectric layer is generated on the graphene layer by heating the reactor to a second reaction temperature and then forming the HfO₂ gate dielectric layer with an ALD process on the graphene layer through a reaction between a hafnium source and water acting as oxidizer.

Further, it is preferred that the second reaction temperature is in a range of from 200° C. to 350° C.

Further, it is preferred that the hafnium source is tetrakis(ethylmethylamido)hafnium.

The method of the present invention is mainly characterized in that the metal oxide film acting as the nucleation layer is formed through a reaction between the metal source and water which acts as oxidizer and is physically absorbed to the surface of graphene. This enables a HfO₂ gate dielectric film to be prepared later on graphene with an ALD process to have good uniformity, a high coverage rate, and a high quality and prevents the defects which may degrade the performance of the graphene-based field effect transistor from entering the crystal lattice of graphene.

### BRIEF DESCRIPTION OF THE DRAWINGS

Other and further objects, features, and advantages of the invention will be more explicit from the following detailed description taken with reference to the drawings wherein:

FIG. 1 is a flow chart showing a method of fabricating a graphene-based field effect transistor according to the present invention; and

FIGS. 2 to 4 are views showing fabrication of the graphene-based field effect transistor according to the flowchart shown in FIG. 1.

### DETAILED DESCRIPTION OF THE INVENTION

The inventors of the present invention have found that performances of graphene-based field effect transistors are unfavorably affected by problems existent in the prior art such as that an oxide gate dielectric layer prepared on a surface of graphene has poor uniformity, a low coverage rate and a large quantity of defects and that a crystal structure of graphene is destroyed.

Therefore, to prevent formation of the defects in fabricating the graphene-based field effect transistor, the inventors of the present invention have improved the prior art and proposed a new method of fabricating the graphene-based field effect transistor which is mainly characterized in that a metal oxide film is grown as a nucleation layer before formation of a HfO₂ gate dielectric layer to improve quality of the HfO₂ gate dielectric layer.

Now referring to the drawings, preferred embodiments of the invention are described below. The present invention provides the preferred embodiments, but is not limited thereto. In the drawings, layers and regions are appropriately magnified to clearly show a reaction structure thereof, but it should not be considered to strictly show a proportional relation of geometry size as an illustrative view. What is shown in the drawings is illustrative and should not be considered to limit the scope of the present invention.

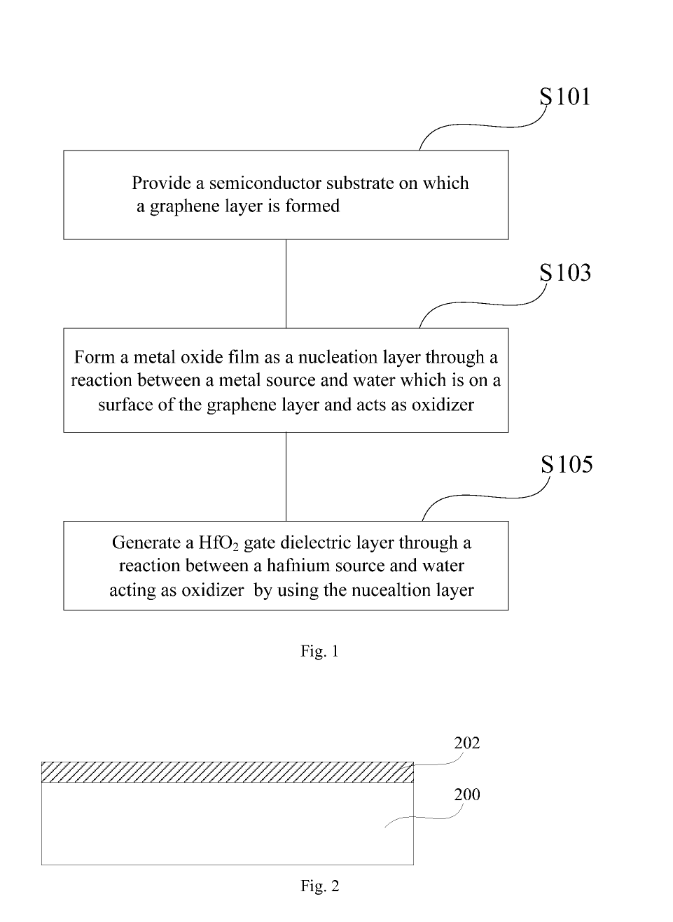

FIG. 1 is a flow chart showing a method of fabricating a graphene-based field effect transistor according to the invention. As shown in FIG. 1, the method includes the following steps:

a step identified with S101 of providing a semiconductor substrate which has a non-functionized graphene layer grown thereon;

a step identified with S103 of forming a metal oxide film as a nucleation layer through a reaction between a metal source and water which is physically absorbed to a surface of the graphene layer and acts as oxidizer; and

a step identified with S105 of generating a HfO₂ gate dielectric layer through a reaction between a hafnium source and water acting as oxidizer by using the nucleation layer.

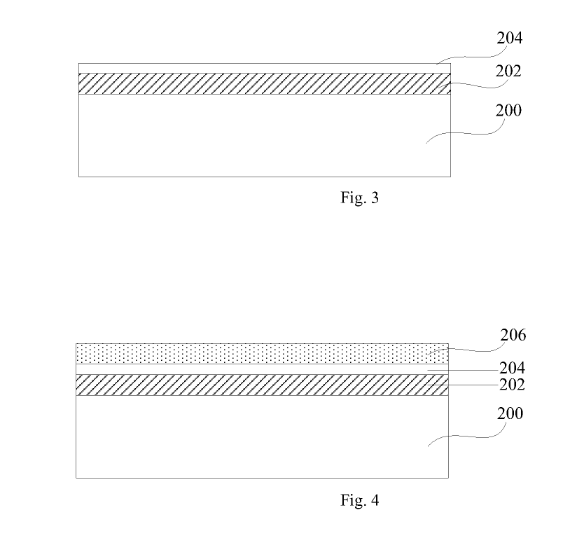

Firstly, the step of S100 is performed. Specifically, a semiconductor substrate 200 is provided and a graphene layer 202 is formed thereon as shown in FIG. 2.

The semiconductor substrate 200 is a silicon substrate with a semiconductor device formed thereon. Alternatively, the silicon substrate may have silicon oxide partially formed thereon. Also, the semiconductor substrate 200 may be a silicon-on-insulator with a semiconductor device formed thereon, or may be a II-VI or III-V compound semiconductor with a semiconductor device formed thereon.

The graphene layer 202 is non-functionized which is formed in practical applications by transferring a fresh and non-functionized graphene sample to the semiconductor substrate 200. However, it is not limited thereto. The graphene layer 202 may be directly formed on the semiconductor substrate 200 using other processes in other embodiments, and the related description is omitted herein for brevity.

Next, the step of S103 is carried out. Specifically, a metal oxide film is formed as a nucleation layer 204 through a reaction between a metal source and water which is physically absorbed to a surface of the graphene layer 202 and acts as oxidizer. Therefore, a structure is formed as shown in FIG. 3.

The surface of the graphene layer is hydrophobic and lacks dangling bonds required for growing films. A high-k gate dielectric film has problems such as poor uniformity and a low coverage rate when prepared directly on the graphene layer 202 by the H₂O-based ALD film growing process, thus affecting unfavorably performance of semiconductor devices. Therefore, the inventors of the present invention have thought of growing the nucleation layer 204 on the graphene layer 202 before formation of the high-k gate dielectric film.

The inventors of the present invention have found that water molecules may be physically absorbed to a surface of graphene and creatively proposed that a metal oxide layer is formed as the nucleation layer 204 through a reaction between a metal source and water which is physically absorbed to the surface of the graphene layer 202 and acts as oxidizer.

Specifically, in the step of S103 of forming the nucleation layer 204, the semiconductor substrate 200 having the graphene layer 202 described in the step of S101 is transferred into an ALD reactor, and then the ALD reactor is heated to a first reaction temperature which is, for example, 100° C. to 140° C. Through a reaction between an aluminum source and water which is physically absorbed to the surface of the graphene layer 202 and acts as oxidizer, an Al₂O₃ film is subsequently formed as the nucleation layer 204 with the H₂O-based ALD process by repeating a reaction cycle thereof plural times. Particularly, in the embodiment, the metal source is the aluminum source which is preferably trimethylaluminum (TMA).

The ALD process is a self-limiting growth process based on sequential surface chemistry. When using the ALD process, surface reactants may be taken out by a cleaning step. A typical ALD growth process is formed by repeating a reaction cycle plural times, the reaction cycle including steps of: a) introducing the first gas-phase reactants into a reactor; b) removing the reactants which are not absorbed from a thus-obtained product by using neutral gas; c) introducing the second gas-phase reactants into the reactor subsequently followed by a reaction between the second gas-phase reactants and the first gas-phase reactants absorbed to a surface of the grown film; and d) removing both reaction by-products and the second gas-phase reactants which are not absorbed from a thus-obtained product. In this embodiment, the H₂O-based ALD process is adopted, and the introduced reactants include water and the aluminum source. Further, the formed film is obtained by repeating the reaction cycle 10 to 35 times and has a thickness of 1.5 nm to 5 nm. In another embodiment, other metal sources may be used to grow the metal film as the nucleation layer, and the related description is omitted herein for brevity.

In the step of S105, using the nucleation layer 204, a HfO₂ gate dielectric layer 206 is grown on the graphene layer 202 as shown in FIG. 4 through a reaction between a hafnium source and water acting as oxidizer.

Specifically, in the step of S105, the ALD reactor is heated up to a second reaction temperature which is, for example, 200° C. to 350° C., and the HfO₂ gate dielectric layer is produced by the H₂O-based ALD process on the nucleation layer 204 through a reaction between the hafnium source and water acting as oxidizer. In the present embodiment, tetrakis(ethylmethylamido)hafnium (TEMAH) is used as the hafnium source, but it is not limited thereto. For example, tetrakis (dimethylamino) hafnium (TDEAH) or HfCl₄ may also be used.

The experiments show that the HfO₂ gate dielectric layer 206 can have advantages such as good uniformity and a high coverage rate by forming the nucleation layer 204 on the graphene layer 202 firstly and then further forming the high-k HfO₂ gate dielectric layer 206 on the nucleation layer 204.

In addition, in comparison with the O₃-based ALD process, the H₂O-based ALD process adopted in the invention can prevent the crystal structure of graphene from being destroyed and inhibit the defects from being introduced.

Next, a gate electrode, a source region, a drain region and the like can be successively formed using the prior art to finish fabricating the graphene-based field effect transistor, and the related description is omitted herein for brevity.

To sum up, in the present invention, the metal oxide layer is formed as the nucleation layer through the reaction between the metal source and water which acts as oxidizer and is physically absorbed to the surface of graphene, and then the high-quality HfO₂ gate dielectric film with good uniformity, a high coverage rate and a low content of defects is prepared subsequently using the ALD process. Meanwhile, by adopting the H₂O-based ALD process, the defects that may degrade the performances of the graphene-based field effect transistor can be prevented from entering the crystal lattice of graphene in fabricating the HfO₂ gate dielectric film.

The above description of the detailed embodiments is only to illustrate the preferred implementation according to the present invention, and it is not to limit the scope of the present invention. Accordingly, all modifications and variations completed by those with ordinary skill in the art should fall within the scope of present invention defined by the appended claims.

1. A method of fabricating a graphene-based field effect transistor, comprising steps of:
providing a semiconductor substrate on which a non-functionized graphene layer is formed;
forming a metal oxide film as a nucleation layer through a reaction between a metal source and water which acts as oxidizer and is physically absorbed to a surface of the graphene layer; and
generating a HfO₂ gate dielectric layer through a reaction between a hafnium source and water acting as oxidizer by using the nucealtion layer.

2. The method of claim 1, wherein the graphene layer is formed on the semiconductor substrate by transferring a non-functionzied graphene sample to the semiconductor substrate.

3. The method of claim 1, wherein the metal oxide film is Al₂O₃ film, and the Al₂O₃ film is formed by repeating a reaction cycle composed of steps of:
transferring the semiconductor substrate having the graphene layer to a reactor;
heating the reactor to a first reaction temperature; and
generating the Al₂O₃ film with an ALD process through a reaction between an aluminum source and water which acts as oxidizer and is physically absorbed to the surface of the graphene layer.

4. The method of claim 3, wherein the first reaction temperature is in a range of from 100° C. to 140° C.

5. The method of claim 3, wherein the aluminum source is trimethylaluminum.

6. The method of claim 3, wherein the Al₂O₃ film is obtained by repeating the reaction cycle 10 times to 35 times.

7. The method of claim 3, wherein a thickness of the Al₂O₃ film is in a range of from 1.5 nm to 5 nm.

8. The method of claim 1, wherein the HfO₂ gate dielectric layer is generated on the graphene layer by heating the reactor to a second reaction temperature and then forming the HfO₂ gate dielectric layer with an ALD process on the graphene layer through a reaction between a hafnium source and water acting as oxidizer.

9. The method of claim 8, wherein the second reaction temperature is in a range of from 200° C. to 350° C.

10. The method of claim 8, wherein the hafnium source is tetrakis(ethylmethylamido)hafnium.

11. The method of claim 3 , wherein the HfO₂ gate dielectric layer is generated on the graphene layer by heating the reactor to a second reaction temperature and then forming the HfO₂ gate dielectric layer with an ALD process on the graphene layer through a reaction between a hafnium source and water acting as oxidizer.

12. The method of claim 11, wherein the second reaction temperature is in a range of from 200° C. to 350° C.

13. The method of claim 11, wherein the hafnium source is tetrakis(ethylmethylamido)hafnium.
